(19) United States
(12) Patent Application Publication
(10) Pub. No.: US 2008/0163889 A1
(43) Pub. Date: Jul. 10, 2008

(54) MEGASONIC TRANSDUCER MATCHING NETWORK FOR WET CLEAN CHAMBERS

(75) Inventors: Constantin Predoaica, Boise, ID (US); Paul E. Lester, Emmett, ID (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC.

(21) Appl. No.: 11/620,590

(22) Filed: Jan. 5, 2007

(51) Int. Cl. B08B 3/12; H03H 7/38

(52) U.S. Cl. 134/1; 134/56 R; 333/17.3

(57) ABSTRACT

The present invention generally provides a cost-effective method and apparatus for matching power source and transducer load impedances for an array of acoustic-wave transducers used in wet processing chambers. In one embodiment, a single radio frequency generator provides power to multiple megasonic transducers. Each transducer contains multiple piezoelectric crystals, and each processing chamber includes multiple megasonic transducers.

### BACKGROUND OF THE INVENTION

1. Field of the Invention

Embodiments of the present invention generally relate to systems that use solutions for cleaning substrates. In particular, embodiments of the invention relate to impedance matching networks for megasonic transducers used in wet processing chambers.

2. Description of the Related Art

Substrate surface preparation and cleaning is an essential step in the semiconductor manufacturing process. Multiple cleaning steps can be performed. The process recipe may include etch, clean, rinse, and dry steps. The combination is referred to as wet bench processing. Wet bench processing is often performed upon batches of substrates housed in a cassette. The cassette is exposed to a variety of process and rinse chemicals in multiple vessels. The vessel may have piezoelectric transducers to propagate megasonic energy into the vessel's cleaning solution. The megasonic energy enhances cleaning by inducing microcavitation in the cleaning solution, helping to dislodge particles off of the substrate surfaces.

One type of tool provides a number of the process steps in one vessel upon a batch of substrates. This “one vessel” tool eliminates substrate transfer steps, has a reduction in fabrication facility footprint size, and reduces the risk of breakage and particle contamination by eliminating the need to transfer substrates between tools. However, batch sonic cleaning has seen limited success since each substrate of the batch is exposed to a different level of sonic energy, often resulting in non-uniform cleaning of the substrates. This limitation has led to the development of a single substrate cleaning chamber that can perform multiple process steps and provide greater control and effectiveness of the sonic cleaning. The chamber may include multiple megasonic transducers, each of which is positioned at a different location about the substrate to optimize cleaning results. To increase throughput, several chambers may be included on a single tool.

Each megasonic transducer in the chamber is typically powered by a radio frequency (RF) generator since each transducer typically includes one or more piezoelectric crystals which require powers signals of a sinusoidal nature to function properly. Proper functioning of the transducer also requires the efficient transfer of power from the RF generator to the transducer. Efficient power transfer is typically achieved by matching the impedance of the RF generator (source) to the impedance of the transducer (load). The matching of source impedance to load impedance is typically achieved using matching circuitry that may include inductors, capacitors, and transformers.

Typically, for each transducer, there is a separate RF generator and matching circuit connected between. Unfortunately, as the number of transducers increase, the corresponding matching devices and RF generators add significant cost and complexity to a single tool. Therefore, there is a need for a network of matching devices and RF generators that can efficiently deliver power to multiple transducers at reduced cost.

### SUMMARY OF THE INVENTION

Aspects of the invention provide a wet processing system which includes: multiple chambers for processing substrates; multiple acoustic-wave transducers positioned to generate waves in fluids contained in the chambers; and at least one impedance-matching network apparatus. The impedance-matching network apparatus may include an input interface to receive a radio frequency (RF) signal from an RF power source, an output interface to output RF signals generated from the received RF signal to the transducers, and load matching circuitry adapted to match a load impedance of the transducers to a source impedance of the power source at an operating frequency.

Another aspect of the invention provides an impedance-matching network apparatus that includes: an input interface to receive a radio frequency (RF) signal from an RF power source; an output interface to output RF signals generated from the received RF signal to multiple acoustic-wave transducers; and load matching circuitry adapted to match a load impedance of the transducers to a source impedance of the power source at an operating frequency.

Yet another aspect of the invention provides a method for controlling multiple acoustic-wave transducers positioned to generate waves in fluids contained in one or more chambers of a wet processing system. This method includes: providing radio frequency (RF) signals generated from a single RF power source to the transducers from an impedance-matching network apparatus; and matching a load impedance of the transducers to a source impedance of the power source at an operating frequency with the impedance-matching apparatus.

### BRIEF DESCRIPTION OF THE DRAWINGS

FIG. 1 illustrates a cross sectional view of a substrate processing chamber.

FIG. 2 is an orthographic view of a transducer assembly.

FIG. 3 illustrates a partial cross sectional view of a substrate transfer assembly used with the processing chamber of FIG. 1.

FIG. 4 is a schematic view of one embodiment of a matching network for an array of megasonic transducers.

FIG. 5 is a schematic view of one embodiment of a matching circuit.

### DETAILED DESCRIPTION

Embodiments of the present invention may be utilized to reduce cost and complexity in multi-chamber cleaning systems utilizing multiple transducers. For some embodiments, a matching network adapter circuit may allow a single RF generator to drive multiple acoustic-wave (e.g., megasonic) transducers. Depending on the embodiment, the multiple transducers driven by a single RF generator may be located on different cleaning chambers or at different positions in the same chamber. In either case, by reducing the number of RF generators, overall system cost and complexity may be significantly reduced.

In the following description, embodiments will be described with reference to chambers that hold a cleaning fluid (not shown), in which one or more substrates (e.g., wafers) are submerged. Megasonic transducers receive power from (are driven by) an RF generator. The impedance of the transducer (“load”) and the impedance of the RF generator (“source”) may require impedance matching, which may be achieved using matching network adapters connected therebetween. These matching network adapters may be adjusted or “tuned” so that the load impedance matches the source impedance, allowing efficient power transfer between the RF generator and the transducer, which may improve the sonic cleaning of the substrates

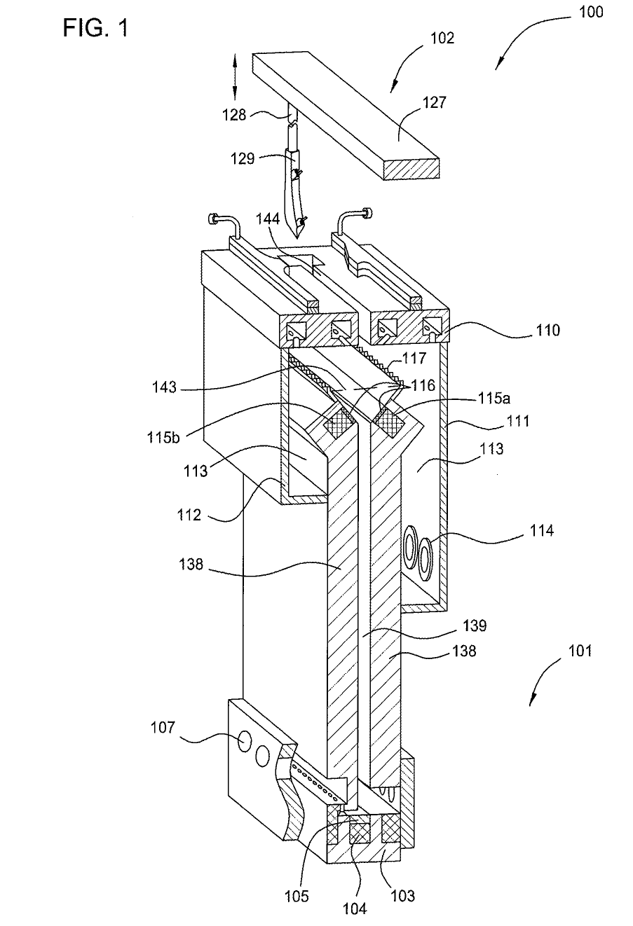

FIG. 1 illustrates a cross sectional view of a substrate processing chamber 100 that may utilize impedance matching in accordance with embodiments of the present invention to drive multiple transducers with a single RF generator. The substrate processing chamber 100 comprises a chamber body 101 configured to retain a liquid and/or a vapor processing environment and a substrate transfer assembly 102 configured to transfer a substrate in and out the chamber body 101.

The lower portion of the chamber body 101 generally comprises side walls 138 and a bottom wall 103 defining a lower processing volume 139. The lower processing volume 139 may have a rectangular shape configured to retain fluid for immersing a substrate, such as a semiconductor wafer, therein. A weir 117 is formed on top of the side walls 138 to allow fluid in the lower processing volume 139 to overflow. The upper portion of the chamber body 101 comprises overflow members 111 and 112 configured to collect fluid flowing over the weir 117 from the lower processing volume 139. The upper portion of the chamber body 101 further comprises a chamber lid 110 having an opening 144 formed therein. The opening 144 is configured to allow the substrate transfer assembly 102 to transfer at least one substrate in and out the chamber body 101.

Each of the plurality of inlet ports 107 may be connected with an independent fluid source, such as chemicals for etching, cleaning, and DI water for rinsing, such that different fluids or combination of fluids may be supplied to the lower processing volume 139 for different processes. As the processing fluid fills up the lower processing volume 139 and reaches the weir 117, the processing fluid overflows from the weir 117 to an upper processing volume 113 and is connected by the overflow members 111 and 112. A plurality of outlet ports 114 configured to drain the collected fluid may be formed on the overflow member 111.

A liquid vapor interface 143 may be created in the chamber body 101. In one embodiment, the processing liquid fills up the lower processing volume 139 and overflows from the weir 117 and the liquid vapor interface 143 is located at the same level as the weir 117.

In one embodiment, a megasonic transducer 104 is disposed behind a window 105 in the bottom wall 103. The megasonic transducer 104 is configured to provide megasonic energy to the lower processing volume 139. The megasonic transducer 104 may comprise a single transducer or an array of multiple transducers, oriented to direct megasonic energy into the lower processing volume 139 via the window 105.

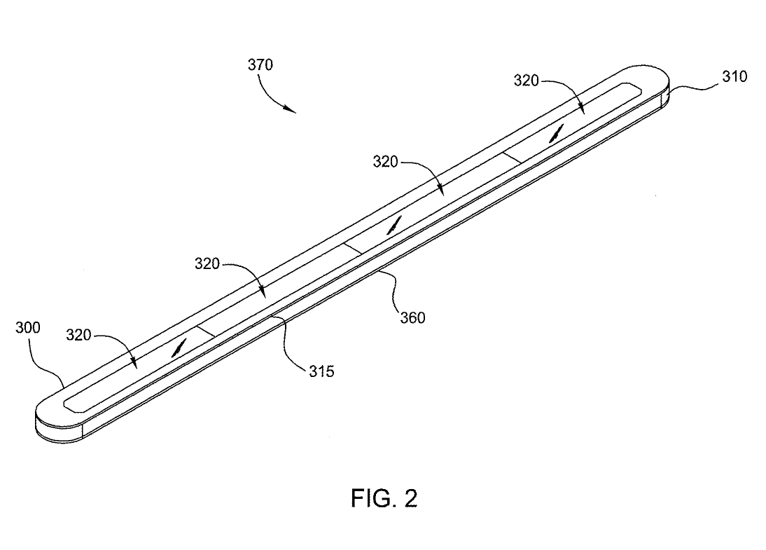

FIG. 2 illustrates a transducer assembly 370, including an array of piezoelectric crystals, that may be used as the transducers in the process chamber 100. For example, the assembly 370 may represent each of the three transducers (104, 115a, 115b) and windows (105, 116) in the process chamber 100. The transducer assembly shown includes four piezoelectric crystals 320, an interconnect board 360, and an electrically conducting contact ring 310. In other embodiments, the transducer assembly may include one or more piezoelectric crystals. The transducer assembly includes a sapphire lens 300 which is bonded to four piezoelectric crystals 320 using an electrically conducting adhesion layer 315. The sapphire lens forms one external surface of the assembly, and comes into direct contact with the cleaning fluid of the process chamber. The sapphire lens 300 is bonded to the contact ring 310 using an electrically conducting adhesion layer 315. The interconnect board 360, which may include a printed circuit board, is bonded to the other side of the contact ring 310 to form transducer assembly 370.

The conducting adhesion layer adhesion 315 makes electrical contact with one side of each piezoelectric crystal 320 and the contact ring 310 to form a ground electrode. The opposite side of each crystal is typically deposited with a metal layer which covers the entire surface area to form a signal electrode so that electrodes are formed on opposite sides of each piezoelectric crystal 320. Suitable connection means, which may include the use of conducting springs for the signal electrodes, are used to connect each electrode of each crystal to the interconnect board 360. A voltage difference may then be applied across each piezoelectric crystal 320 so as to excite the crystal at the frequency of a radio frequency (RF) voltage supplied by an RF generator. This voltage may be applied through a coaxial cable (not shown) which is attached to the interconnect board 360.

Returning to FIG. 1, when the megasonic transducer 104 directs megasonic energy into processing fluid in the lower processing volume 139, acoustic streaming, i.e. streams of micro bubbles, within the processing fluid may be induced. The acoustic streaming aids the removal of contaminants from the substrate being processed and keeps the removed particles in motion within the processing fluid hence avoiding reattachment of the removed particles to the substrate surface.

In one embodiment, a pair of megasonic transducers 115a, 115b, each of which may comprise a single transducer or an array of multiple transducers, are positioned behind windows 116 at an elevation below that of the weir 117, and are oriented to direct megasonic energy into an upper portion of lower processing region 139. The transducers 115a and 115b are configured to direct megasonic energy towards a front surface and a back surface of a substrate respectively.

The transducers 115a and 115b are preferably positioned such that the energy beam interacts with the substrate surface at or just below a gas/liquid interface 143, e.g. at a level within the top 0-20% of the liquid in the lower processing volume 139. The transducers may be configured to direct megasonic energy in a direction normal to the substrate surface or at an angle from normal. Preferably, energy is directed at an angle of approximately 0-30 degrees from normal, and most preferably approximately 5-30 degrees from normal. Directing the megasonic energy from the transducers 115a and 115b at an angle from normal to the substrate surface can have several advantages. For example, directing the energy towards the substrate at an angle minimizes interference between the emitted energy and return waves of energy reflected off the substrate surface, thus allowing power transfer to the solution to be maximized. It also allows greater control over the power delivered to the solution. It has been found that when the transducers are parallel to the substrate surface, the power delivered to the solution is highly sensitive to variations in the distance between the substrate surface and the transducer. Angling the transducers 115a and 115b reduces this sensitivity and thus allows the power level to be tuned more accurately. The angled transducers are further beneficial in that their energy tends to break up the meniscus of fluid extending between the substrate and the bulk fluid (particularly when the substrate is drawn upwardly through the band of energy emitted by the transducers)-thus preventing particle movement towards the substrate surface.

Additionally, directing megasonic energy at an angle to the substrate surface creates a velocity vector towards the weir 117, which helps to move particles away from the substrate and into the weir 117. For substrates having fine features, however, the angle at which the energy propagates towards the substrate front surface must be selected so as to minimize the chance that side forces imparted by the megasonic energy will damage fine structures.

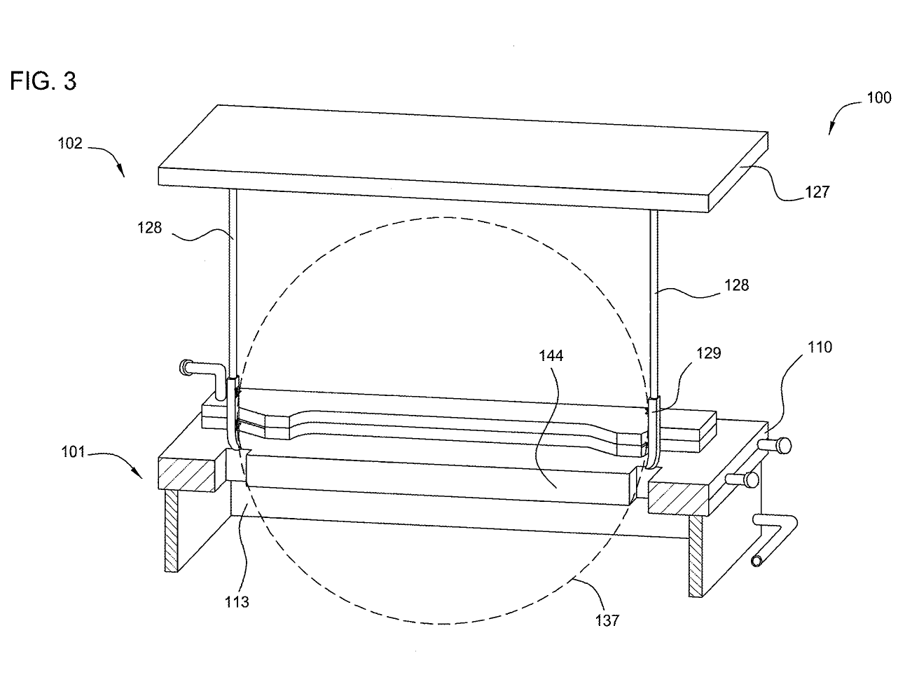

Referring to FIG. 3, the substrate transfer assembly 102 may include a pair of posts 128 connected to a frame 127. The frame 127 may be connected with an actuator mechanism configured to move the substrate transfer assembly 102 vertically. An end effecter 129 configured to receive and secure a substrate 137 by an edge is connected to a terminal end of each of the posts 128. Each of the end effecters 129 is configured to provide lateral and radial support to the substrate 137 while the substrate transfer assembly 102 moves the substrate 137 to and from the chamber body 101.

In one embodiment of the present invention, the substrate transfer assembly 102 may be suitably modified so that three substrates 137 may be processed in unison for a single tool that has three processing chambers 100. Other embodiments may include other modifications to the substrate transfer assembly 102 so that a different number of (two or more) multiple substrates may be processed in unison for a tool that has multiple processing chambers.

As previously described, conventional systems utilizing multiple chambers and multiple transducers per chamber required a separate RF generator and matching circuit for each transducer, increasing system cost. However, embodiments of the present invention may allow a single RF generator and matching circuit pair to be used to drive multiple transducers, which may significantly reduce system cost and complexity.

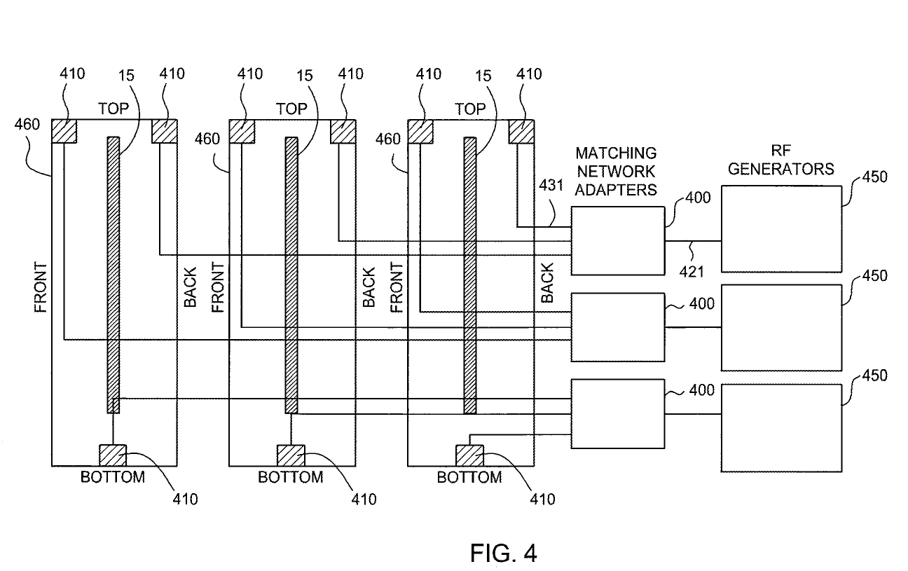

For example, FIG. 4 is a schematic view of one embodiment of the present invention for a matching network for an array of megasonic transducers for a single tool that includes multiple wet processing chambers. In this embodiment, each cleaning chamber 460 may represent chamber 100, and each transducer assembly 410 may represent assembly 370. In other embodiments, each transducer assembly may operate at a frequency other than megasonic. Each matching network adapter 400 is connected to three transducer assemblies 410 using three power signal transmission cables 431. The chamber 410 has sides which may be referred to as top, bottom, front and back. In this embodiment, one matching network adapter 400 may be connected to three transducers 410 located at the top and back of each chamber 460; a second network adapter 400 may be connected to three transducers 410 located at the top and front of each chamber 460; and a third network adapter 400 may be connected to three transducers 410 located at the bottom of each chamber 460. Each matching network adapter 400 is connected to an RF generator 450 using a power signal transmission cable 421. In this embodiment, the power signal transmission cables 431 and 421 may be coaxial cables, each having an impedance of about 50 ohms. While the example shown in FIG. 4 depicts one RF generator driving three transducers, one transducer per chamber, other embodiments of the present invention may include one RF generator driving multiple transducers, each transducer in a single chamber, or all transducers within a single chamber. Additionally, the matching network adapter may be suitably modified to enable the aforesaid embodiments.

Each cleaning chamber 460 holds a cleaning fluid (not shown), and a substrate 15 is placed within the cleaning fluid. In this embodiment, each RF generator 450 is connected in parallel with three megasonic transducer assemblies 410. Each megasonic transducer 410 receives power signals from an RF generator 450. In the present embodiment, the impedance of the RF generator 450 is about 50 ohms, and the impedance of each transducer 410 is about 50 ohms. The matching network adapter 400 matches the source (RF generator) impedance to the load impedance. The load impedance includes the impedance of each transducer assembly 410 and the impedance created by the mechanical load on each transducer as the transducer creates sonic waves within the cleaning fluid.

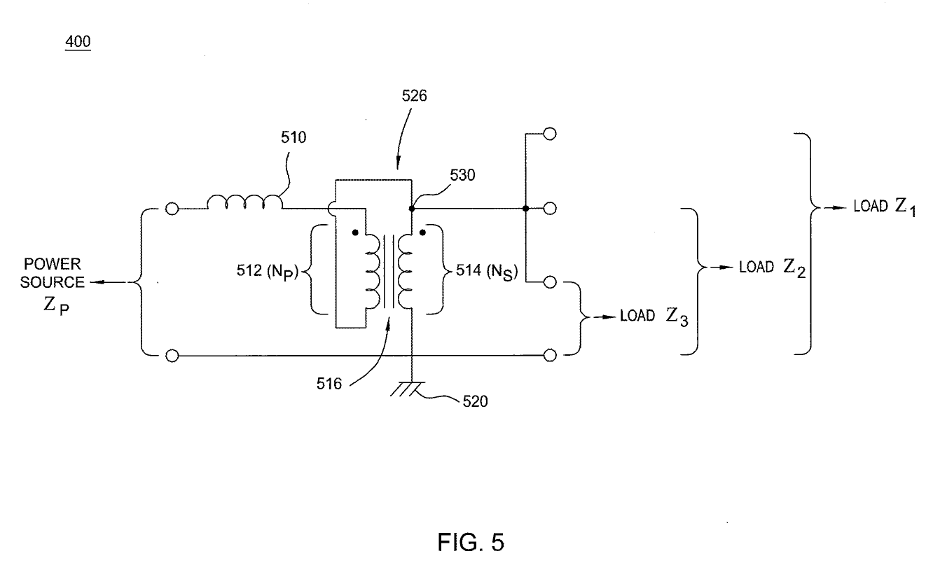

In FIG. 5, one embodiment of the matching circuit for the matching network adapter 400 is shown. An RF power source has impedance Z_{P} and the three impedances Z₁, Z₂, and Z₃ are the load impedances of the three megasonic transducer assemblies under load conditions. In the embodiment of the present invention, these three impedances are nearly identical. The matching circuit includes a type of impedance-matching transformer 526, which is sometimes referred to as an impedance-matching balun. A more common power transformer has two distinct primary and secondary windings. The transformer 526, on the other hand, has a first winding section 512 with N_{P} turns, and a second winding section 514 with N_{S} turns. A node point 530 between the turns allows three loads represented by Z₁, Z₂, and Z₃ to be connected across the second winding section 514. The other side of the second winding section 514 connects to a chassis ground 520. The first winding 512 functions as a primary coil, and the second winding 514 as a secondary coil. The magnetic coupling of the windings is strengthened by a ferromagnetic core 516. The transformer is connected in series with an inductor 510. In other embodiments of the present invention, other types of transformers may be used.

One of the properties of a transformer is that it can transform impedances. In particular,

Z_{P}=(N_{P}/N_{S})²Z_{S},

where Z_{P} is the impedance at the input of the transformer on the primary side; N_{P}/N_{S} is the turn ratio of primary windings to secondary windings, and Z_{S} is the impedance seen at the output of the transformer on the secondary side. In the embodiment of the present invention, Z_{P} may represent the impedance of the RF generator 450, and Z_{S} may represent the total transducer load impedance which includes the three transducer impedances Z₁, Z₂, and Z₃. In this example, the transmission line 421 impedance may be included in Z_{P} and the impedances for transmission lines 431 included in Z_{S}. By adjusting the turn ratio N_{P}/N_{S} and the value of the inductor 510, the source and load impedances may be matched so that power can be efficiently transferred from the RF generator to the transducers.

In one embodiment of the present invention, the values for the turn ratio N_{P}/N_{S} and inductor 510 may be determined using a testing chamber which can simulate megasonic transducer load impedances that would be encountered during typical substrate processing conditions. Three transducer assemblies 410 may be installed into a testing chamber and connected to a matching network adapter 400. In this embodiment, the transducer assembly 370 may represent assembly 410. The matching network adapter 400 may then be connected to an RF generator 450. The power signal transmission cables used to connect the components of the matching network may be very similar or identical to cables 421 and 431 so that the cables do not introduce new impedance values to the matching network being tested. The testing chamber may then filled with a liquid which simulates the cleaning fluid used during substrate processing. In the present embodiment, deionized water may be used to simulate the cleaning fluid. The transducers 410 may then be driven by the RF generator 450 under simulated load conditions so that Z₁, Z₂, and Z₃ represent load impedances for typical substrate processing conditions. The matching circuit shown in FIG. 5 may then be tuned by adjusting the turn ratio N_{P}/N_{S} and the value of the inductor 510. The turn ratio and inductor values are adjusted or tuned until the source and load impedance values are suitably matched and the transducers operate at a predetermined level of power efficiency. In the present embodiment, the turn ratio and inductor values are then fixed for the matching network adapter 400. In one embodiment of the present invention, the source and load impedances are suitably matched at a frequency of about 925 kHz.

The transducers 410 and network adapter 400 that are installed on the testing chamber during the tuning process may be suitably marked (e.g., serialization marking) so that they may be used together when installed as a matching network on a multi-chamber tool. In another embodiment, the circuit of FIG. 5 may be suitably modified so that the matching network adapter remains adjustable and can be tuned during application set-up or during tool operation to match impedances for the RF source and transducer load.

1. A wet processing system, comprising:
a plurality of chambers for processing substrates;
a plurality of acoustic-wave transducers positioned to generate waves in fluids contained in the chambers; and
at least one impedance-matching network apparatus comprising an input interface to receive a radio frequency (RF) signal from an RF power source, an output interface to output RF signals generated from the received RF signal to the transducers, and load matching circuitry adapted to match a load impedance of the transducers to a source impedance of the power source at an operating frequency.

2. The system of claim 1, wherein multiple substrates are processed in unison, with at least one substrate per processing chamber.

3. The system of claim 1, wherein the impedance matching network apparatus outputs RF signals to multiple transducers located in a common chamber.

4. The system of claim 1, wherein the impedance matching network apparatus outputs RF signals to multiple transducers located in at least two different chambers.

5. The apparatus of claim 1, wherein the transducers are located to direct waves towards a substrate at angles different from normal to the substrate.

6. The apparatus of claim 1, wherein the operating frequency is a megasonic frequency.

7. The apparatus of claim 6, wherein each matching network adapter is connected to three megasonic transducers.

8. An impedance-matching network apparatus, comprising:
an input interface to receive a radio frequency (RF) signal from an RF power source;
an output interface to output RF signals generated from the received RF signal to multiple acoustic-wave transducers; and
load matching circuitry adapted to match a load impedance of the transducers to a source impedance of the power source at an operating frequency.

9. The apparatus of claim 1, wherein the output interface is adapted to connect with at least three transducers that are used in a wet processing tool.

10. The apparatus of claim 9, wherein the matching network adapter is connected to at least three megasonic transducers.

11. The apparatus of claim 9, wherein the at least three transducers are located in at least two different chambers.

12. The apparatus of claim 9, wherein at least two of the at least three transducers are located in a single chamber.

13. The apparatus of claim 8, wherein each transducer contains one or more piezoelectric crystals.

14. The apparatus of claim 8, wherein the operating frequency is a megasonic frequency.

15. A method of controlling a plurality of acoustic-wave transducers positioned to generate waves in fluids contained in one or more chambers of a wet processing system, comprising:
providing radio frequency (RF) signals generated from a single RF power source to the transducers from an impedance-matching network apparatus; and
match a load impedance of the transducers to a source impedance of the power source at an operating frequency with the impedance-matching apparatus.

16. The method of claim 15, further comprising utilizing a testing chamber to adjust one or more parameters of the impedance-matching apparatus.

17. The method of claim 16, wherein the one or more parameters include at least one inductor value or one matching transformer turn ratio value.

18. The method of claim 15, wherein the operating frequency is about 925 kHz.

19. The method of claim 15, wherein providing RF signals to the transducers from an impedance-matching network apparatus comprises providing RF signals to multiple transducers located in a common chamber.

20. The method of claim 15, wherein providing RF signals to the transducers from an impedance-matching network apparatus comprises providing RF signals to transducers located in different chambers.
